(19) United States
(12) Patent Application Publication
(10) Pub. No.: US 2026/0161843 A1
(43) Pub. Date: Jun. 11, 2026

(54) DYNAMIC DIGITAL TWIN CLUSTER FORMATION AND OPERATION

(71) Applicant: Dell Products L.P., Round Rock, TX (US)

(72) Inventors: Mohammad Alavirad, Kanata (CA); Said Tabet, Austin, TX (US); Ali Esswie, Calgary (CA)

(21) Appl. No.: 18/972,279

(22) Filed: Dec. 6, 2024

(51) Int. Cl. G06F 30/20

(52) U.S. Cl. CPC G06F 30/20

(57) ABSTRACT

Individual digital twin models that represent different functions, or entity functions, may compose a digital twin cluster that represents a digital twin model that is more complex than each of the separate individual digital twins. Digital twin cluster members may determine a master individual digital twin corresponding to the cluster based on digital twin capability scores corresponding to the digital twin models or based on conditions that may relate to radio communication links between members of the cluster. An individual digital twin may be dynamically added to, or deleted from, a cluster based on weighting of various factors, including historical outcomes, or based on changing conditions corresponding to a communication link between devices corresponding to the digital twin and the cluster. Determining a digital twin outcome corresponding to the cluster may be based on outcome information reported by secondary digital twins to the master digital twin model.

### BACKGROUND

The ‘New Radio’ (NR) terminology that is associated with fifth generation mobile wireless communication systems (“ G”) refers to technical aspects used in wireless radio access networks (“RAN”) that comprise several quality of service classes (QoS), including ultrareliable and low latency communications (“URLLC”), enhanced mobile broadband (“eMBB”), and massive machine type communication (“mMTC”). The URLLC QoS class is associated with a stringent latency requirement (e.g., low latency or low signal/message delay) and a high reliability of radio performance, while conventional eMBB use cases may be associated with high-capacity wireless communications, which may permit less stringent latency requirements (e.g., higher latency than URLLC) and less reliable radio performance as compared to URLLC. Performance requirements for mMTC may be lower than for eMBB use cases. Some use case applications involving mobile devices or mobile user equipment such as smart phones, wireless tablets, smart watches, and the like, may impose on a given RAN resource loads, or demands, that vary. A RAN node may activate a network energy saving mode to reduce power consumption. A NR RAN node may comprise a Distributed Unit (“DU”), a Centralized Unit (“CU”), or a Radio Unit (“RU”). One or more of a DU, CU, and RU may be collocated or may be located at one or more different locations.

The terminology ‘digital twin’ (“DT”) may refer to a digital replica, or model, that may mimic a physical entity, a process, or a system and may be used to simulate, analyze, or optimize performance of the physical entity, process, or system in real time. Digital twin technology has been used in various fields including aerospace, manufacturing, healthcare, urban planning, and production, transmission, and delivery of energy. The National Aeronautical and Space Administration (“NASA”) did early development work with respect to digital twin technology to improve maintenance and operation of spacecraft, wherein physical entities and systems were digitally mirrored/mimicked to monitor and predict behavior of the entities and systems while operating during space missions, thus enhancing the ability to simulate operation of system in a space environment and the ability to troubleshoot and optimize systems remotely while an entity or system is actually operating in a space environment.

### SUMMARY

The following presents a simplified summary of the disclosed subject matter in order to provide a basic understanding of some of the various embodiments. This summary is not an extensive overview of the various embodiments. It is intended neither to identify key or critical elements of the various embodiments nor to delineate the scope of the various embodiments. Its sole purpose is to present some concepts of the disclosure in a streamlined form as a prelude to the more detailed description that is presented later.

In an example embodiment, a method may comprise facilitating, by at least one discoverable computing system comprising at least one processor configured to execute at least one discoverable model, communicating at least one discoverable model class capability indication, to be usable by at least one discovering computing system, indicative of at least one discoverable model class capability corresponding to the at least one discoverable computing system and facilitating, by the at least one discoverable computing system, receiving, from at least one discovering computing system, at least one discovering model class capability indication indicative of at least one discovering model class capability corresponding to the at least one discovering computing system. Based at least on one of the at least one discovering model class capability indication or the at least one discoverable model class capability indication, the method may further comprise determining, by the at least one discoverable computing system, at least one discoverable model class score corresponding to the at least one discoverable computing system and at least one discovering model class score corresponding to at least one of the at least one discovering computing system to result in at least one determined discoverable model class score and at least one determined discovering model class score. The method may further comprise analyzing, by the at least one discoverable computing system, the at least one determined discoverable model class score with respect to the at least one determined discovering model class score to result in at least one analyzed determined discoverable model class score. Based on the at least one analyzed determined discoverable model class score, the method may further comprise determining, by the at least one discoverable computing system, a discoverable cluster membership level corresponding to the at least one discoverable computing system to result in a determined discoverable cluster membership level that corresponds to a computing system cluster that comprises the at least one discoverable computing system and at least one of the at least one discovering computing system. The method may further comprise facilitating, by the at least one discoverable computing system, communicating at least one discoverable cluster membership level indication, indicative of the determined discoverable cluster membership level, to be usable by the at least one discovering computing system to determine, based on at least one determined discovering model class score determined by the at least one discovering computing system, at least one discovering cluster membership level corresponding to the at least one discovering computing system and operating, by the at least one discoverable computing system, according to the determined discoverable cluster membership level.

The determined discoverable cluster membership level may comprise a leader level corresponding to the at least one discoverable computing system being a leader of the computing system cluster. The at least one determined discoverable model class score may be determined to be higher than the at least one determined discovering model class score.

In an example embodiment, the at least one determined discoverable model class score is determined to be higher than the at least one determined discovering model class score by the at least one discoverable computing system. In an example embodiment, the at least one determined discoverable model class score may be determined to be higher than the at least one determined discovering model class score by the at least one discovering computing system.

In an example embodiment, the at least one determined discoverable cluster membership level may comprise a first determined discoverable cluster membership level. The at least one determined discoverable model class score may comprise a first determined discoverable model class score. The at least one discoverable cluster membership level indication may comprise a first discoverable cluster membership level indication. The method further comprise determining, by the at least one discoverable computing system a second determined discoverable model class score and determining, by the at least one discoverable computing system, a second determined discovering model class score corresponding to the at least one discovering computing system. Based on the second determined discovering model class score being determined to not be greater than the second determined discoverable model class score, the method may further comprise determining, by the at least one discoverable computing system, a second discoverable cluster membership level that does not comprise a leader level corresponding to the at least one discoverable computing system being a leader of the computing system cluster. The method may further comprise facilitating, by the at least one discoverable computing system, communicating, to the at least one discovering computing system, a second discoverable cluster membership level indication indicative of the second discoverable cluster membership level indication.

In an example embodiment, the method may further comprise facilitating, by the at least one discoverable computing system, communicating, to the at least one discovering computing system cluster, configuration information. The configuration information may comprise at least one of: at least one cluster indication indicative of the computing system cluster, a ping periodicity indication indicative of at least one ping periodicity according to which the at least one discoverable computing system is to communicate acknowledgements with respect to the at least one discovering computing system, at least one cluster score criterion to be applicable with respect to the to the at least one discoverable model class score or the at least one discovering model class score to be used to determine membership in the computing system cluster, at least one score offset to be applicable with respect to analysis of the at least one discoverable model class score or the at least one discovering model class score with respect to the at least one cluster score criterion, or at least one score calculation mode indication indicative of at least one score calculation mode.

In an example embodiment, the at least one score calculation mode indication may comprise at least one of: a local mode indication indicative that the at least one discovering model class score is to be determined by the at least one discovering computing system or an external mode indicative of the at least one discovering model class to be determined by the at least on discoverable computing system.

In an example embodiment, the determining of the at least one determined discoverable model class score may be determined based on at least one of: the at least one discoverable model class capability or the at least one discovering model class capability, at least one confidence level corresponding to at least one of the at least one discoverable computing system or the at least one discovering computing system, at least one prediction accuracy corresponding to at least one of the at least one discoverable computing system or the at least one discovering computing system, at least one network connectivity quality corresponding to at least one of the at least one discoverable computing system or the at least one discovering computing system, at least one energy efficiency corresponding to at least one of the at least one discoverable computing system or the at least one discovering computing system, at least one data freshness value corresponding to at least one of the at least one discoverable computing system or the at least one discovering computing system, or at least one update periodicity corresponding to at least one of the at least one discoverable computing system or the at least one discovering computing system. The at least one determined discoverable model class score may be prioritized based on the at least one confidence level or based on other factors.

The at least one determined discovering model class score may be determined by the at least one discovering computing system based on at least one of: the at least one discoverable model class capability or the at least one discovering model class capability, at least one confidence level corresponding to at least one of the at least one discoverable computing system or the at least one discovering computing system, at least one prediction accuracy corresponding to at least one of the at least one discoverable computing system or the at least one discovering computing system, at least one network connectivity quality corresponding to at least one of the at least one discoverable computing system or the at least one discovering computing system, at least one energy efficiency corresponding to at least one of the at least one discoverable computing system or the at least one discovering computing system, at least one data freshness value corresponding to at least one of the at least one discoverable computing system or the at least one discovering computing system, or at least one update periodicity corresponding to at least one of the at least one discoverable computing system or the at least one discovering computing system. At least one of the at least one discoverable model or the at least on discovering model may comprise at least one digital twin model.

In another example embodiment, a first computing device, may comprise at least one processor configured to process executable instructions that, when executed by the at least one processor, facilitate performance of operations, that may comprise transmitting, to a second computing device, at least one first model class capability indication indicative of at least one first model class capability corresponding to the first computing device and receiving, from the second computing device, at least one second model class capability indication indicative of at least one second model class capability corresponding to the second computing device. Based at least on one of the at least one first model class capability indication or the at least one second model class capability indication, the operations may further comprise determining a first model class score corresponding to the first computing device or a second model class score corresponding to the second computing device to result in a determined first model class score or a determined second model class score. The operations may further comprise analyzing the determined first model class score with respect to the determined second model class score to result in an analyzed determined first model class score. Based on the analyzed determined first model class score, the operations may further comprise determining at least one first cluster membership level corresponding to the first computing device to result in a determined first cluster membership level that corresponds to a computing device cluster that comprises at least the first computing device and the second computing device. The operations may further comprise transmitting a first cluster membership level indication, indicative of the determined first cluster membership level, to be usable by the second computing device to determine a second cluster membership level corresponding to the second computing device and operating with respect to the computing device cluster according to the determined first cluster membership level.

In an example embodiment, the at least one first cluster membership level may correspond to the first computing device being a cluster master corresponding to the computing device cluster, wherein the operating according to the determined first cluster membership level comprises managing model output report information corresponding to the computing device cluster. The operations may further comprise transmitting, to the second computing device, at least one acknowledgement request and failing to receive, from the second computing device, at least one acknowledgement response responsive to the at least one acknowledgement request to result in at least one failed acknowledgement. Based on the at least one failed acknowledgement, the operations may further comprise transmitting, to the second computing device, at least one master halting indication indicative that the first computing device is not the cluster master. The operations may further comprise halting the managing model output report information corresponding to the computing device cluster.

In an example embodiment, the at least one first cluster membership level may correspond to the first computing device being a cluster non-master corresponding to the computing device cluster. The operations further comprise determining an updated first model class score corresponding to the first computing device to result in a determined updated first model class score. Based on the determined updated first model class score, the operations may further comprise determining an updated first cluster membership level corresponding to the first computing device to result in a determined updated first cluster membership level that corresponds to the computing device cluster. The operations may further comprise transmitting an updated first cluster membership level indication, indicative of the determined updated first cluster membership level corresponding to the first computing device being a master of the computing device cluster and operating with respect to the computing device cluster according to the determined updated first cluster membership level, wherein the operating according to the determined updated first cluster membership level comprises managing model output report information corresponding to the computing device cluster.

In an example embodiment, the first computing device may comprise a first wireless transmit receive unit. The second computing device may comprise at least one second wireless transmit receive unit. The computing device cluster may comprise a sidelink group comprising the first computing device and the second computing device. The first computing device may comprise a remote wireless transmit receive unit and the second computing device may comprise a relay wireless transmit receive unit. The first computing device may comprise a leader of the computing device cluster configured to facilitate communication between the second computing device and a wireless radio access network node according to at least one sidelink channel resource corresponding to the sidelink group.

In yet another example embodiment, a non-transitory machine-readable medium may comprise executable instructions that, when executed by at least one processor of a first computing system that may be configured to execute a first model node corresponding to a first physical entity, may facilitate performance of operations that may comprise directing, to a second computing system configured to execute a second model node corresponding to a second physical entity, at least one first model class capability indication indicative of at least one first model class capability corresponding to the first model node and receiving, from the second computing system, at least one second model class capability indication indicative of at least one second model class capability corresponding to the second model node. Based at least on one of the at least one first model class capability indication or the at least one second model class capability indication, the operations may further comprise determining a first model class score corresponding to the first model node or a second model class score corresponding to the second model node to respectively result in a determined first model class score or a determined second model class score. The operations may further comprise analyzing the determined first model class score with respect to the determined second model class score to result in an analyzed determined first model class score. Based on the analyzed determined first model class score, the operations may further comprise determining at least one first cluster membership level corresponding to the first model node to result in a determined first cluster membership level that corresponds to a model cluster that comprises at least the first model node and the second model node. The operations may further comprise directing a first cluster membership level indication, indicative of the determined first cluster membership level, to the second computing system to be usable by the second computing system to determine a second cluster membership level corresponding to the second computing system and operating the first model node with respect to the model cluster according to the determined first cluster membership level.

In an example embodiment, at least one of the first model class score or the second model class score may be based on at least one of: at least one inter-node latency between the first model node and the second model node, at least one bandwidth availability corresponding to at least one of the first model node or the second model node, or at least one computational load distribution corresponding to a first computational loading corresponding to the first model node or a second computational loading corresponding to the second model node.

In an example embodiment, at least one of the first model node or the second model node may correspond to a first digital twin node or a second digital twin node, respectively. The first digital twin node or second digital twin node may be configured to determine at least one parameter metric corresponding to at least one parameter associated with the model cluster.

In an example embodiment, at least one of the first digital twin node or the second digital twin node may correspond to a vehicle entity cluster. At least one vehicle entity associated with the vehicle entity cluster may be configured to use information generated by the first digital twin node or the second digital twin node to facilitate operation of the at least one vehicle entity.

### BRIEF DESCRIPTION OF THE DRAWINGS

FIG. 1 illustrates a digital twin computing system.

FIG. 2 illustrates example digital twin nodes informing other digital twin nodes of digital twin function capabilities.

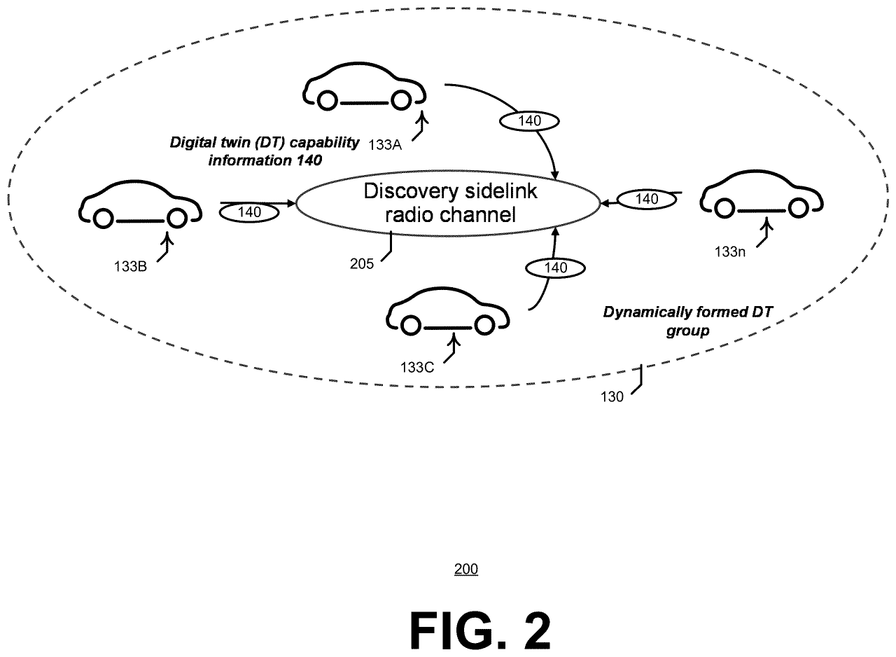

FIG. 3 illustrates an example determined master digital twin node establishing itself as the master digital twin node.

FIG. 4 illustrates an example determined master digital twin node being unelected, by non-master digital twin nodes, as a determined master digital twin node.

FIG. 5 illustrates example digital twin cluster configuration information.

FIG. 6 illustrates a timing diagram of dynamic configuration of a digital twin cluster of at least one digital twin node.

FIG. 7 illustrates a block diagram of an example method embodiment.

FIG. 8 illustrates a block diagram of an example computing system.

FIG. 9 illustrates a block diagram of an example non-transitory machine-readable medium embodiment.

FIG. 10 illustrates an example computer environment.

### DETAILED DESCRIPTION OF THE DRAWINGS

As a preliminary matter, it will be readily understood by those persons skilled in the art that the present embodiments are susceptible of broad utility and application. Many methods, embodiments, and adaptations of the present application other than those herein described as well as many variations, modifications, and equivalent arrangements, will be apparent from or reasonably suggested by the substance or scope of the various embodiments of the present application.

Accordingly, while the present application has been described herein in detail in relation to various embodiments, it is to be understood that this disclosure is illustrative of one or more concepts expressed by the various example embodiments and is made merely for the purposes of providing a full and enabling disclosure. The following disclosure is not intended nor is to be construed to limit the present application or otherwise exclude any such other embodiments, adaptations, variations, modifications and equivalent arrangements, the present embodiments described herein being limited only by the claims appended hereto and the equivalents thereof.

As used in this disclosure, in some embodiments, the terms “component,” “system” and the like are intended to refer to, or comprise, a computer-related entity or an entity related to an operational apparatus with one or more specific functionalities, wherein the entity can be either hardware, a combination of hardware and software, software, or software in execution. As an example, a component can be, but is not limited to being, a process running on a processor, a processor, an object, an executable, a thread of execution, computer-executable instructions, a program, and/or a computer. By way of illustration and not limitation, both an application running on a server and the server can be a component.

One or more components can reside within a process and/or thread of execution and a component can be localized on one computer and/or distributed between two or more computers. In addition, these components can execute from various computer readable media having various data structures stored thereon. The components can communicate via local and/or remote processes such as in accordance with a signal having one or more data packets (e.g., data from one component interacting with another component in a local system, distributed system, and/or across a network such as the internet with other systems via the signal). As another example, a component can be an apparatus with specific functionality provided by mechanical parts operated by electric or electronic circuitry, which is operated by a software application or firmware application executed by a processor, wherein the processor can be internal or external to the apparatus and executes at least a part of the software or firmware application. In yet another example, a component can be an apparatus that provides specific functionality through electronic components without mechanical parts, the electronic components can comprise a processor therein to execute software or firmware that confers at least in part the functionality of the electronic components. While various components have been illustrated as separate components, it will be appreciated that multiple components can be implemented as a single component, or a single component can be implemented as multiple components, without departing from example embodiments.

The term “facilitate” as used herein is in the context of a system, device or component “facilitating” one or more actions or operations, in respect of the nature of complex computing environments in which multiple components and/or multiple devices can be involved in some computing operations. Non-limiting examples of actions that may or may not involve multiple components and/or multiple devices comprise transmitting or receiving data, establishing a connection between devices, determining intermediate results toward obtaining a result, etc. In this regard, a computing device or component can facilitate an operation by playing any part in accomplishing the operation. When operations of a component are described herein, it is thus to be understood that where the operations are described as facilitated by the component, the operations can be optionally completed with the cooperation of one or more other computing devices or components, such as, but not limited to, sensors, antennae, audio and/or visual output devices, other devices, etc.

Further, the various embodiments can be implemented as a method, apparatus or article of manufacture using standard programming and/or engineering techniques to produce software, firmware, hardware, or any combination thereof to control a computer to implement the disclosed subject matter. The term “article of manufacture” as used herein is intended to encompass a computer program accessible from any computer-readable (or machine-readable) device or computer-readable (or machine-readable) storage/communications media. For example, computer readable storage media can comprise, but are not limited to, magnetic storage devices (e.g., hard disk, floppy disk, magnetic strips), optical disks (e.g., compact disk (CD), digital versatile disk (DVD)), smart cards, and flash memory devices (e.g., card, stick, key drive). Of course, those skilled in the art will recognize many modifications can be made to this configuration without departing from the scope or spirit of the various embodiments.

With respect to discussion of digital twin technology, various terminology may be used, including ‘physical entity’, which may refer to a real-world, tangible object or system that is being replicated digitally and can be anything from a manufacturing machine to an entire smart city. Other terminology may include ‘digital model’, which may refer to a virtual model that mirrors or mimics a physical entity and that may use data from sensors, IoT devices, and other data sources corresponding to the physical entity to represent the physical entity's structure or behavior. A ‘data connection’ may facilitate at least one real-time data flow, comprising data collected by, or generated by, sensors or Internet of Things (“IoT”) technology, between at least one physical entity and a corresponding digital twin that mirrors/mimics the at least one physical entity, thus enabling real-time monitoring and analysis of data corresponding to the at least one physical entity using the at least one digital twin model. A digital twin model may use advanced analytics, machine learning (“ML”), or artificial intelligence (“AI”) to process incoming data received according to a data connection. A digital twin model may be able to simulate various scenarios, predict outcomes, and provide insights for decision-making with respect to at least one physical entity to which the digital twin model corresponds. A prediction, simulated outcome, or other insight generated by a digital twin model may be referred to as an output or an outcome of the digital twin model.

Digital twin technology may facilitate numerous applications and benefits with respect to different technology or industry sectors. With respect to manufacturing, digital twin technology may be used to optimize production processes, to improve product quality, or to reduce downtime of a physical entity based on predictive maintenance with respect to the physical entity facilitated by a digital twin model corresponding to the physical entity. Digital twin technology may facilitate a manufacturer simulating production lines, identifying bottlenecks, or implementing improvements without disrupting operations. With respect to healthcare, a patient-specific digital twin model may facilitate determining a personalized treatment plan prediction corresponding to disease progression. Digital twin technology may also facilitate development and testing of medical devices or pharmaceutical products. With respect to urban planning, digital twin technology may facilitate smart urban planning, infrastructure management, or sustainability initiatives. By simulating traffic patterns, energy usage, and environmental impacts, city planners can use information generated by a digital twin model to make informed decisions that may enhance urban living. With respect to the energy sector, digital twin technology may facilitate optimizing performance of power plants, grids, or renewable energy sources and may help in predicting equipment failures, optimizing maintenance schedules, or improving energy efficiency. Digital twin technology may facilitate autonomous operation of vehicles. A central digital twin model may interact with distributed digital twin models being executed by computing systems at one or more vehicles that may be operating as a cluster of vehicles or at least one entity functionality (e.g., vehicle prediction of a road condition, a hazard condition, a weather condition, a traffic condition, a wireless connectivity performance condition, or other condition). The vehicle functionality may be distributed amongst computing systems, corresponding to the cluster of vehicles, that may determine amongst themselves a leader computing system that may manage analysis of outcomes generated by digital twins corresponding to the at least one distributed functionality.

However, adoption of and use of digital twin technology faces several challenges. Integrating diverse data sources that may produce data or information in various formats or sizes, or at various periods or intervals, and presenting data to a digital twin model accurately and consistently is complex. Developing and maintaining digital twin models for large-scale systems, such as smart cities, may require significant computational resources and sophisticated algorithms. Protecting sensitive data and ensuring cybersecurity in interconnected digital twin systems are desirable goals.

Advancements in IoT, AI, and cloud computing are expected to further enhance the capabilities and adoption of digital twin technology, and as AI, IoT, and cloud computing technology evolves, digital twin models may become more sophisticated, providing deeper insights with respect to physical entities and facilitating proactive and efficient management of physical systems/entities.

In a wireless communication context, AI and ML (AI and ML may be collectively referred to as “AI/ML”), may facilitate cellular and backhaul embodiments that offer a wide set of performance and operational advantages such as network automation, signaling overhead reduction, energy saving, and capacity enhancement. The virtual nature of DT models can effectively simulate, or emulate, behavior of a physical entity or component thereof, or an entire physical system, thus facilitating proactive design optimizations, proactive fault detection, and predictive maintenance. However, implementing a complex DT by a central computing system, for example a computing system implemented by a computing system that is responsible for managing and processing data with respect to multiple physical entities, may require very robust processing and computing capabilities. For a DT to realistically and accurately reflect or predict behavior of a physical entity/system, the DT must be well-designed with modeled conditions being almost-identical to conditions corresponding to the real/physical entity/system. Thus, the larger and more diverse a DT model (e.g., the DT is designed to mimic/mirror multiple entities, multiple interfaces, etc.), the more complex the respective DT model becomes. Such complexity accordingly may result in a DT requiring a significant amount of signaling overhead for data collection (e.g., more communication resources may be needed to deliver data via a data connection for a complex DT as compared to resource needed to delivered data with respect to a more simple DT) with respect to each physical entity, system, or interface, to report back real-time condition information to an entity (e.g., a computing server system) that may be facilitating execution of the DT that may be central with respect to multiple entities being modeled by the DT. Moreover, a single, complex, central DT may require significant processing capability to facilitate high-performance modeling of an entire physical system, and such processing capability may be challenging to satisfy by processing capability available at a central computing system that may be facilitating operation of a complex, central DT.

To solve problems related to processing and computing capability corresponding to a central computing system, configured to execute a complex central DT model, being overwhelmed facilitating the complex central DT model, DT functionality outcome(s) may be determined by distributed, or federated, DT models located remotely with respect to the central computing system, wherein, instead of a single, central, complex DT model being implemented by the central computing system, one or more DT functions corresponding to the complex DT model may be delegated and distributed to computing systems associated with multiple entities, which may be referred to as distributed entities or delegated entities, wherein each delegated/distributed entity may execute a smaller/lighter and less complex DT as compared to a single, central, complex DT. Distributing DT functionality outcome determination from being executed by a complex central model/DT node to being executed by one or more computing systems corresponding to distributed entities may facilitate a central computing system implementing a simpler central model, operating in an energy-efficient or processing-efficient manner as compared to operation of a single complex DT model. A multi-node DT implementation that represents, or models, multiple physical entities and that facilitates sharing of local DT intelligence and outcomes among multiple collaborating nodes may increase performance of DT modeling compared to performance of a single/central complex DT model that attempts to model all of the multiple physical entities. However, both cellular/radio (e.g., 5G and higher) and backhaul communication interface links may need to be optimized to facilitate higher performance communication of DT information from remote distributed DT models to and from a central DT model. To facilitate communication of DT information associated with distributed DT models, regardless of the actual DT design and implementation (e.g., disregarding design of each distributed/local DT), embodiments disclosed herein may facilitate sharing of DT data and information wherein multiple distributed nodes (e.g., multiple distributed DT models respectively corresponding to multiple distributed physical entities), each executing a local, low-complexity DT, may share information to and from a central computing system that may be executing central DT that may be less complex than if distributed DT models did not facilitate the central DT model. Outcomes and information generated by distributed DT models may be delivered to a central DT model without the central DT needing to consume processing resources to determine the information generated by the distributed DT model(s).

According to example embodiments disclosed herein, regardless of actual DT design or implementation, an adaptive DT group, or cluster, may be formed that may comprise multiple DT nodes, which could be nodes, or devices executing DT models, supplied by different manufacturers or vendors, to facilitate dynamically sharing or combining intelligence (e.g., DT model outcome(s)) corresponding to at least one DT node. Distributed, or federated, DT implementations that may comprise multiple heterogeneous DT nodes may collaborate, or share outcome information, to facilitate representation of a complex system. To minimize signaling resource and processing loading problems, standardized protocols, as disclosed herein, may facilitate dynamic DT cluster formation and intelligence sharing with respect to cellular/radio communication networks (e.g., 5G and beyond) or backhaul interface links.

According to embodiments disclosed herein, a distributed consensus method may facilitate consistency and fault-tolerance with respect to formation of a cluster that comprises multiple, distributed, DT nodes. DT nodes may be added or removed from being a part of, or a member of, a DT cluster, or group, of DT nodes, without compromising integrity of the cluster and may facilitate dynamic, cross-vendor collaboration of DT outcome information. In example embodiments disclosed herein, a per-node dynamic scoring method may facilitate reliably determining sharing of DT outcomes generated by individual DT nodes. In an example, a scoring method embodiment may determine a DT confidence score corresponding to a DT node based on multiple factors that may comprise at least one of: at least one computational capability corresponding to the node, a historical accuracy with respect to predictions generated by the node, at least one network connectivity quality value or stability value, a least one energy efficiency value corresponding to the node, or at least on data freshness value or update frequency value corresponding to the node. Thus, DT outcomes generated by nodes corresponding to a higher confidence score may be prioritized, with respect to outcomes generated by nodes corresponding to lower confidence scores, to facilitate determining an outcome of a more complex DT model to which outcomes of the nodes may be inputs. It will be appreciated that a DT node confidence score may be based on, or may not be based on, a learning model confidence level corresponding to the DT node. Dynamic scoring methods disclosed herein may facilitate real-time adaptation and optimization of a collaborative DT network (e.g., cluster of DT nodes) to increase a likelihood that data used to generate an outcome corresponding to a DT represented by a DT cluster is reliable and relevant. According to example embodiments disclosed herein, DT outcomes corresponding to different DT nodes that may compose a DT cluster (e.g., the nodes may comprise vehicle devices, 5G wireless radio access network node (“RAN”), computing network servers, desktop or laptop computers within a range or proximity of each other, and the like) may be aggregated to proactively optimize overall DT performance without requiring high-processing capabilities at each individual DT node corresponding to a DT that is represented by the cluster. Use case deployments of example embodiments may comprise 5G sidelink deployments, which may be used to facilitate, for example, vehicle-to-vehicle communication, backhaul deployments (e.g., server-to-server communication), or long-range wireless radio deployment (e.g., RAN-node-to-devices or RAN-node-to-connected user equipment devices).

### Dynamic Digital Twin Cluster Formation

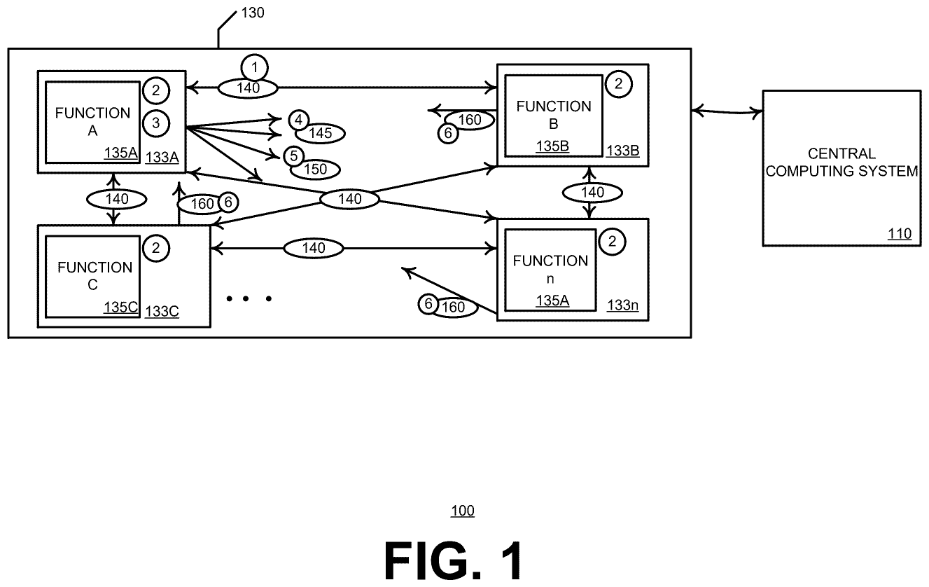

Turning now to FIG. 1, the figure illustrates a system 100 comprising a central computing system 110 and a remote computing system 130, which may be referred to as a cluster, that may comprise at least one remote computing device 133, or node, that may respectively facilitate operation of at least one digital twin function 135. A remote computing system 133 may be referred to as a discoverable device/node or a discovering device/node. For example, if nodes 133 correspond to wireless transmit receive unit (“WTRU”) user equipment (“UE”) devices, devices/nodes 133 may be discoverable with respect to one another via a sidelink protocol, or other device discovery protocol. Accordingly, devices/nodes 133 may be referred to as ‘discoverable’ or ‘discovering’ insofar as the nodes may be discoverable to other nodes and the nodes may attempt discovering other nodes.

At act 1, each of at least one DT node 133A-113n may transmit DT capability information 140 associated with the respective node. In an example embodiment, a DT node 133 may correspond to a sidelink wireless transmit receive unit user equipment device (“WTRU”), such as a smartphone or other device with similar wireless communication capability such as an Internet-of-Things device or a machine-to-machine device, that may communicate with other sidelink nodes 133. In an example embodiment, a sidelink node/WTRU 133 may comprise, or may function as, a roadside radio access network node or a vehicle telematics control unit and may transmit DT capability information 140 as part of sidelink discovery information, Bluetooth discovery, Wi-Fi discovery and the like according to a standard protocol that may be established by a standards setting body such as, for example 3GPP, and may comprise at least one information element. Capability information 140 may comprise information pertaining to, or corresponding to, a node 133 that transmits the capability information. Capability information 140 may comprise at least one DT class indication indicative of at least one DT class. A DT class indication may be indicative of: at least one energy efficiency class, at least one load/utilization class, at least one fault detection class, at least one on-board capability class, at least one radio link class, and the like. Capability information 140 may be indicative of, or may be usable to determine, an overall DT capability, corresponding to a node 133 that transmits the information 140, to perform at least one DT function 135. A DT class corresponding to a node 133 may be based on at least one class parameter, for example, a learning model complexity (e.g., a number of layers corresponding to at least one neural networks corresponding to the) , an update frequency, or at least one resource requirement (e.g., at least one CPU, GPU, memory resource that may be used to perform a function 135 corresponding to the node 133). At least one class parameter may be encoded according to a predefined compact encoding scheme to minimize signaling overhead/wireless resources used to transmit information 140. Transmitting to, or receiving from, other nodes 133, information 140, a node 133 may respectively announce at least one DT capability (e.g., at least one DT function 135) to the other nodes or may receive from at least one other node 133 at least one DT capability corresponding to the at least one other node. Accordingly, DT nodes 133 that are proximate to one another may be apprised via information 140 of at least one DT capability 135 corresponding to at least one other DT node 133.

At act 2, DT node 133A may be determined to be a node of nodes 133 having a highest reported DT capability with respect to nodes 133A-133n (e.g., DT node 133A may be determined to correspond to a largest number of supported DT classes or functions 135 with respect to other proximate DT nodes 133B-133n) and consequently node 133A may be referred to as a master, or leader, DT node. DT nodes 133 may attempt to determine which of the nearby DT nodes (e.g., nodes proximate with respect to one another based on signal strength values determined with respect to the other nodes) has the highest reported DT capability level by decoding discovery messages 140 received from other nodes 133. Determining node 133A to be a master node may comprise analyzing information received via messages 140 using a weighted scoring algorithm that may evaluate a number of supported DT classes or a sophistication associated with each class. The scoring algorithm may assign different weights to different DT classes or capabilities based on complexity, resource requirements, or overall DT capability corresponding to a particular node 133.

Based on node 133A being determined to correspond to a highest DT capability with respect to other nodes 133 associated with other capability information reports 140, DT node 133A may consider itself as a master with respect to other nodes 133 corresponding to DT cluster 130. At act 4, master node 133A may transmit (e.g., broadcast or multicast) master DT node indication 145 as DT cluster/group information. Based on node 133A determining that node 133A is a master/leader node with respect to other nodes 133B-133n based on having a highest reported DT capability score and based on node 133A announcing itself as a master DT node associated with cluster 130, nodes 133B-133n may operate as non-master, or secondary, DT nodes. For example, master DT node 133A may perform a lead administrative role with respect to DT cluster 130, which may comprise nodes 133A-133n. To perform a lead administrative role with respect to cluster 130, master node 133A should be reachable by (e.g., capable of communicating with) nodes 133B-133n associated with the cluster to facilitate communicating DT outcome intelligence exchanged by secondary nodes 133B-133n. A novel distributed consensus protocol may facilitate nodes of cluster 130 agreeing on the leadership status of node 133A, thus preventing potential conflicts in cluster management.

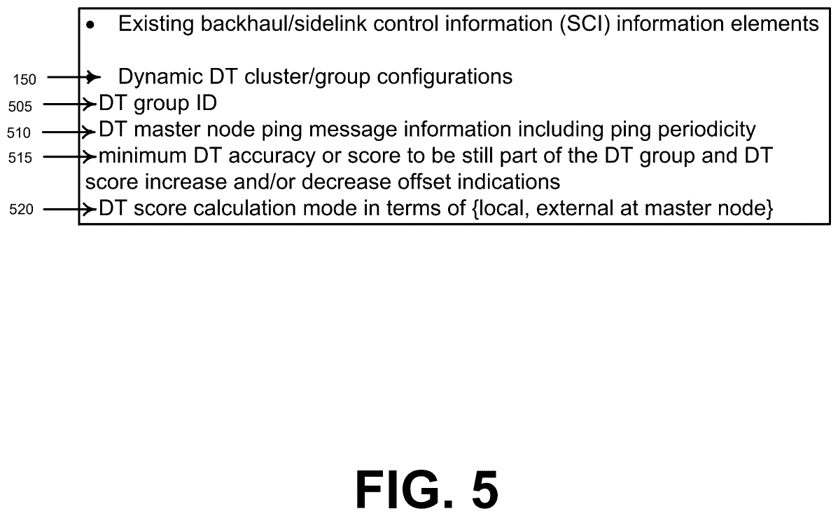

At act 5, master node 133A may transmit dynamic DT cluster/group configuration information 150 toward secondary nodes 133B-133n via a sidelink channel, or other similar communication link corresponding to nodes 133B-133n associated with cluster 130. As shown in FIG. 5, cluster configuration information 150 may comprise in field 505A a DT group/cluster identifier. In field 510 configuration information 150 may comprise DT master node ping message information, which may comprise ping periodicity information. Ping periodicity information indicated in field 510 may comprise timing information usable for master node 133A to respectively transmit and receive acknowledgements (“ACK”) from and to secondary DT nodes 133A-133n to facilitate DT node 133A remaining the master node. Configuration information 150 may comprise in field 515 a minimum DT accuracy criterion or score criterion to be satisfied for a node 133 to become part of, or to remain part of, cluster 130. A criterion included in field 515 may comprise at least one DT score increase or decrease offset indication that may be applicable to an accuracy or score criterion. Configuration information 150 may comprise at least one DT score calculation mode indication indicative of at least one mode to determine a score corresponding to a node associated with cluster 130 in terms of local or external with respect to the master node.

Communicating configuration information 150 may facilitate master node 133A configuring secondary DT nodes 133B-133n with overall DT outcome sharing configurations information. Identification information indicated in field 505 may be usable to facilitate encryption to be used for communication between nodes 133 corresponding to cluster 130. Periodicity information indicated in field 510 may be usable to facilitate master node 133A being reachable by secondary nodes corresponding to cluster 130. Furthermore, information indicated in field 510 may be usable to facilitate master node 133A receiving ping response messages with local DT outcome information (e.g., DT output information determined by at least one DT function 135B-135n) transmitted by DT nodes 133B-133n to master node 133A.

Information indicated in field 515 may indicate a minimum threshold criterion local DT confidence level, accuracy level, or score needed for a secondary node 133B-133n to share its DT outcomes to nearby DT nodes corresponding to DT cluster 130. A confidence/accuracy level or score threshold indicated in field 515 may be dynamically adjusted using a reinforcement learning algorithm to balance inclusivity (e.g., allowing more nodes to be part of cluster 130 and to contribute to a DT being facilitated by DT functions 135) and accuracy (e.g., maintaining high-quality DT cluster outcomes). Thus, information indicated in field 515 may facilitate avoiding outcome information corresponding a poorly performing secondary DT node 133B-133n being permitted to mislead a DT being facilitated or implemented by DT cluster 130.

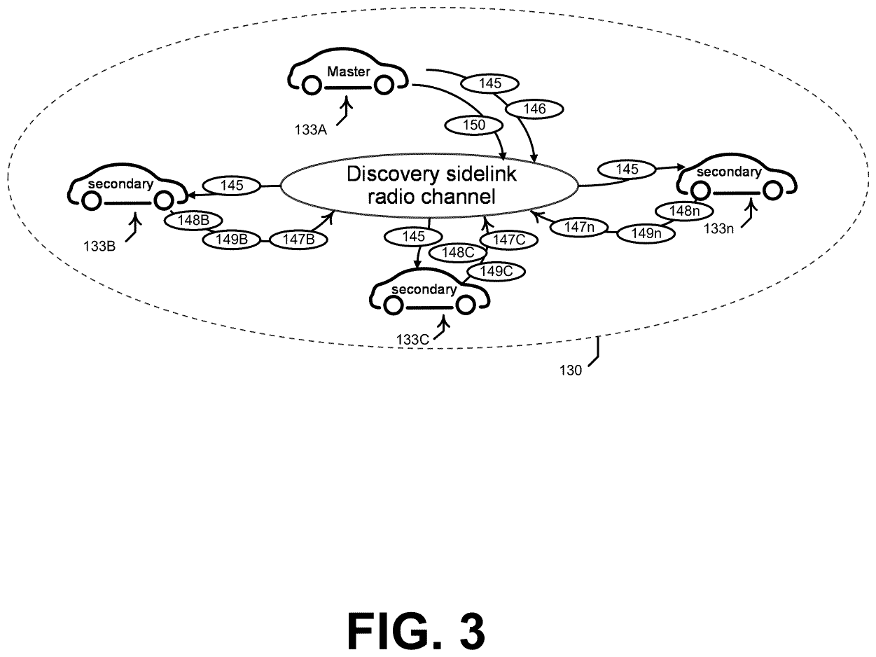

Information indicated by field 520 may facilitate a mode of calculating a per-node DT score, which may be referred to as a model class score. For example, a node DT score may be calculated locally by each secondary DT node 133B-133n wherein at least one secondary node may track and calculate its own DT score and, based on a configured minimum threshold indicated in field 515, a secondary node may or may not determine to share at least one DT corresponding to the secondary node. In another example, master node 133A may calculate at least one per-secondary node real-time DT score and may respectively assign the at least one calculated secondary node score to at least one secondary DT node 133B-133n. The latter example may require a secondary node 133B-133n to periodically report back to master node 133A real time performance indicators 160 at act 6, which indicators may comprise radio performance indicators and non-radio performance indicators corresponding the secondary node. For example, for a link-reliability-focused DT, a secondary node may periodically signal back to a master node a real time packet error rate corresponding to next hops that may facilitate communication of at least one DT outcome associated with the secondary node to the master node to be usable by the master node to calculate a respective DT score corresponding to the secondary node thus removing the burden of such calculation from the secondary node, which may be lower-capability with respect to the master node. Performance indicators 160 may comprise at least one radio condition report 147, at least one DT score report 148, or at least one DT outcome report 149 illustrated in FIG. 3.

Turning now to FIG. 3, master DT node 133A may compile and transmit periodic master node ping frame message(s) 146 via sidelink interface channel 205, or via other broadcast channel(s), toward secondary DT nodes corresponding to cluster 130 associated with a unique cluster identifier indicated by configuration information 150. DT master node 133A may receive radio condition measurement reports 147 or DT outcome reports 149 from secondary DT nodes 133B-133n. In an embodiment, if a local DT score calculation mode is configured by configuration information 150, master DT node 133A may receive from secondary nodes 133B-133n real-time DT score reports 148 to facilitate master node 133A determining to use one of at least one DT outcome reported via at least one report 149 indicative of an outcome corresponding to a function (e.g., a function 135 shown n FIG. 1). For example, for a DT function corresponding to link rata rate, master DT node 133A may prioritize nodes 133B-133n by determining one of at least one outcome reported via at least one message 149 by at least one of nodes 133B-133n indicative of a link data rate corresponding to a node of the secondary nodes having a highest DT score indicated by a message 148 (e.g., based on scores reported via message 148, master node 133A may determine a most reliable and accurate DT node of the at least one node 133B-113n transmitting a report 149 indicative of a link data rate).

Prioritizing, by master node 133A, may comprise using a multi-objective optimization method to evaluate not only a DT score corresponding to the selected link data rate report 149, but that may also evaluate other factors, which may be indicated by a report 149, such as, for example, data freshness, node diversity, or historical accuracy, thus facilitating a decision made by the master node being based on pertinent and relevant information other than just a DT score. In another example embodiment, if an external (e.g., at master node) DT score calculation mode is configured via field 520 in configuration information 150, master DT node 133A may transmit a per-secondary-node DT score that may be determined based on at least one measurement report 147 or outcome report 149 received from secondary DT nodes 133B-133n.

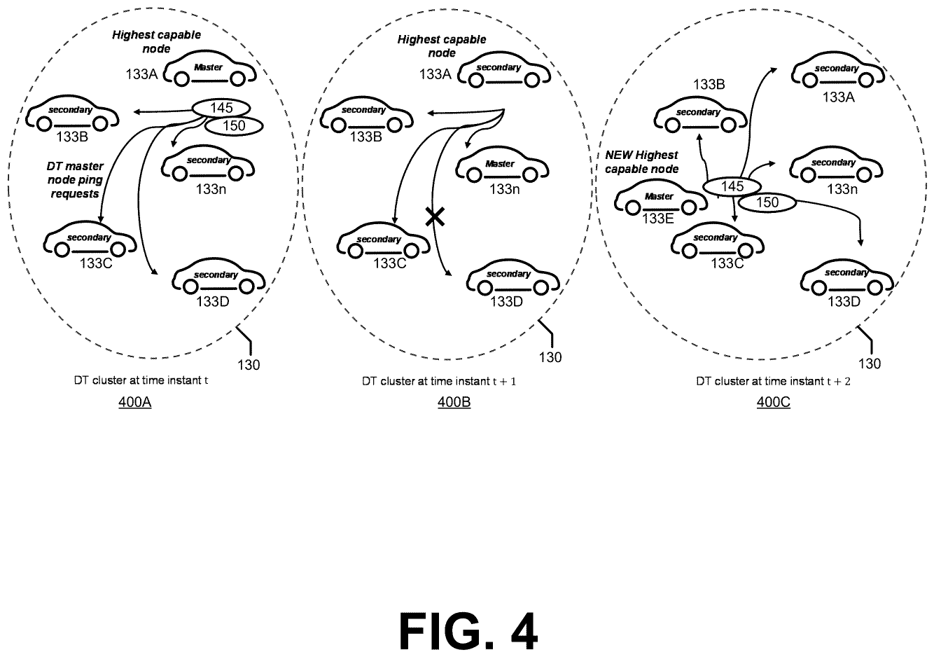

In an embodiment, if no radio link information is received by master node 133A in a measurement report 147 from at least one secondary node 133B-133n in response to master node ping messages 146, or if master node 133A receives from a neighboring secondary DT node 133B-133n a master DT node indication 145 indicative of the neighboring node having a higher DT capability than node 133A, master node 133A may transition from being a master DT node to being a secondary DT node, and may flush, and preemptively halt receiving of secondary node measurement reports and may halt master node processing. Transitioning from being a master DT node to a secondary DT node may be managed by a state machine that ensures smooth handover of master node responsibilities, including the transfer of cluster state information and ongoing DT processes to a new master node. In an example shown in FIG. 4, node 133A may be a master node at instant 400A. At instant 400B, node 133D may determine that master node 133A is unreachable. At instant 400C, node 133E may be part of cluster 130 and may become a new master node.

### Adaptive Digital Twin Cluster Topology Management

In embodiments disclosed herein, a novel adaptive DT cluster topology management system may use a sophisticated graph-based technique that may continuously evaluate a cluster configuration to optimize the cluster. A cluster's composition may be dynamically adjusted based on network conditions, node capabilities, or application requirements (e.g., an application being facilitated by or using output information generated by digital twins of a cluster). A topology management system may implement multi-objective optimization using a graph-based algorithm that continuously evaluates a cluster configuration based on evaluation of multiple factors such as, for example, inter-node latency, bandwidth availability, and computational load distribution. Based on optimization results as determined by a cluster topology management system, the system may dynamically adjust a cluster's structure. The topology management system may dynamically split or merge clusters, add or remove nodes, or adjust a hierarchy of master node/secondary node relationships to optimize overall cluster performance and resilience. Such adaptive optimization may facilitate a DT cluster being efficient and effective during operation with dynamic environments such as may exist with respect to vehicle-to-vehicle environment, vehicle-to-base station environments, or rapidly changing industrial settings. A cluster topology management system may be capable of continuously optimizing a cluster topology based on real-time network conditions and node capabilities.

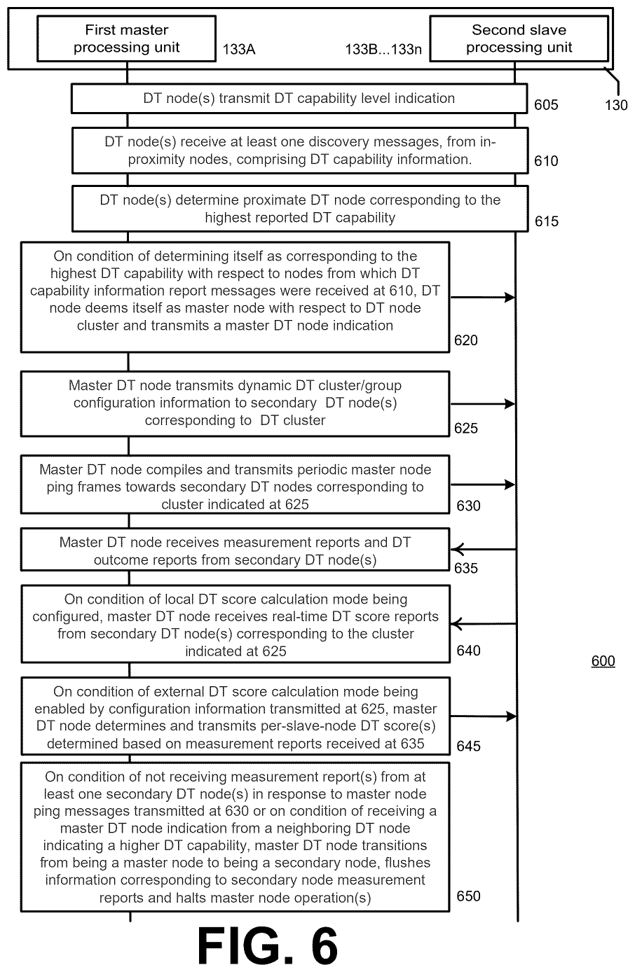

Turning now to FIG. 6, the figure illustrates a timing diagram of an example method to facilitate creation/modification and operation of a DT cluster 130 that may comprise a master computing device 133A, for example a computing device comprising a sidelink WTRU, and at least one secondary computing device 133B-133n, which may also comprise at least one sidelink WTRU. At act 605, at least one digital twin node 133 may transmit at least one DT capability level indication message, for example message 140, described in reference to FIG. 1. A digital twin node may comprise, or may be implemented by, a sidelink WTRU, for example, at least one roadside wireless communication network node stationed along a roadway or at least one vehicle telematics control units operating in a vehicle that may be operating on the roadway, wherein at least one device, for example a smartphone or device that may comprise similar wireless communication modem circuitry as a smartphone, may be configured to communicate with at least one other device that may comprise wireless communication modem circuitry via a side link protocol. The at least one DT capability level indication may be transmitted by a node 133 as part of sidelink discovery information (e.g., information message 140). A DT capability indication message may comprise at least one DT class indication indicative of at least one DT class corresponding to, or that may be facilitated by, a node 133 that may transmit the DT capability indication message. Examples of DT classes may comprise, but are not limited to, an energy efficiency class, a load/utilization class, a fault detection class, an on-board capability class, a radio link class, and the like. In addition to at least one DT class indication, DT capability level indication message may comprise at least one capability score, or capability score vector C=[c₁, c₂, . . . , cₙ], wherein cᵢ represents a capability score corresponding to the i-th DT class, which may be indicated by the at least one DT class indication. At act 610, a DT node 133 may receive at least one discovery message from at least one other DT node 133. At act 615, a DT node 133 may determine a proximate DT node having a reported DT capability that is highest with respect to other proximate DT nodes. A DT node 133 determined to have a highest reported DT capability. or a largest number of supported DT classes, may be deemed by at least one of nodes 133 as a master node. For purposes of example, node 133A may be referred to as having been determined to be a master/leader node. For example, a DT node may correspond to a largest number of supported DT classes and may correspond to a highest overall capability score. A capability score may be determined according to eq. 1, wherein wᵢ may refer to predefined weights respectively corresponding to each at least one DT class.

$$S = \sum ( {w}_{i} \times {c}_{i} ) \qquad Eq . 1$$

At act 620, based on determining itself to have the highest DT capability among DT capability information reports received from nodes 133B-133n, DT node 133A may consider itself, or deem itself, to be master node with respect to nodes 133B-133n, wherein nodes 133A-133n compose DT cluster 130. Master node 133A may transmit, to nodes 133B 133n, at least one master DT node indication, for example indicate 145 described in reference to FIG. 1, as part of a broadcast/multicast DT cluster/group information message. A distributed consensus protocol may be used to facilitate agreement by nodes 133B-133n with node 133A being determined to be the master node of cluster 130.

At act 625, master node 133A may transmit a dynamic DT cluster/group configuration information message, for example configuration information message 150 described in reference to FIG. 1, towards proximate devices that may compose cluster 130. Configuration information message 150 may comprise at least one DT group identifier or indication indicative of cluster 130. Configuration information message 150 may comprise DT master node ping message information that may be indicative of at least one ping periodicity (e.g., a periodicity according to which DT master node 133A may transmit at least one periodic ping message to, or according to which the DT master node may receive ACK messages responsive thereto from secondary DT nodes, to facilitating remaining the master DT node). In an example embodiment, master node 133A may be configured to only remain master node corresponding to cluster 130 as long as ACK messages are received responsive to a periodic ping message from all secondary nodes 133B-133n. Configuration information message 150 may comprise at least one minimum DT accuracy criterion or score criterion to be used by a node 133 to determine whether a node 133 is to become a member of, or is to remain a member of, cluster 130. Configuration information message 150 may comprise at least one DT score increase and/or decrease offset indication of at least one increase and/or decrease offset that may be determined according to a dynamic thresholding method that may be changed according to overall performance of cluster 130. Configuration information message 150 may comprise at least one DT score calculation mode indication indicative of at least one DT score calculation mode, for example a local mode or an external-at-master mode. At least one mode indication may be used to facilitate operation according to a hybrid mode that may combine local and external calculations according to a weighted average.

At act 630, master DT node 133A may compile and transmit at least one period master node ping frame message via a communication link, for example a sidelink communication link, or via at least one broadcast channel toward secondary DT nodes 133B 133n corresponding to cluster 130 that may correspond to a cluster identifier indicated by configuration information 150 that may have been transmitted by the master node at act 625. At act 635, master DT node 133A may receive at least one measurement report (e.g., reported via a message 147 described in reference to FIG. 3) from at least one secondary node 133B-133n or at least one DT outcome report (e.g., reported via a message 149 described in reference to FIG. 3) from at least one secondary DT node. In an embodiment, the at least one measurement report or the at least one DT outcome report may be received via a secure channel. At act 640, on condition of a local DT score calculation mode being configured via configuration information 150, master node 133A may receive real-time DT score reports (e.g., reported via a message 148 described in reference to FIG. 3) from secondary DT nodes 133B-133n and may aggregate scores indicated by the score reports. At act 645, on condition of an external DT score calculation mode (e.g., a score being determined by master node 133A) being configured by configuration information 150, the master DT node may determine and may transmit at least one secondary node DT score respectively corresponding to the at least one secondary node 133B 133n, wherein the at least one secondary node DT score may be determined based on measurement reports or outcome reports received from secondary DT nodes 133B-133n at act 635. An overall DT outcome corresponding to cluster 130 may be updated based on outcomes associated with nodes of the cluster. An overall DT outcome corresponding to cluster 130 may be updated according to scores respectively corresponding to the nodes of the cluster.

At act 650, on condition of not receiving at least one measurement report at act 635 from at least one secondary DT node 133B-133n in response to a master node ping messages transmitted at act 630, or on condition of receiving a master DT node indication from a neighboring secondary DT node (e.g., a node 133B-133n) indicative of the neighboring secondary node has determined that the neighboring secondary node corresponds to a higher DT capability than node 133A, DT node 133A may transition from being a master node to a secondary DT node, and may flush measurement report information corresponding to at least one secondary node measurement report that may have been received at act 635 and may halt operating as a master node. The flushing or halting operation as a master node at act 650 may be facilitated by at least one state transfer protocol that may facilitate seamless handover of cluster management responsibilities and maintaining of cluster stability during transition of node 133A from being a master node corresponding to cluster 130 to being a secondary node corresponding to cluster 130.

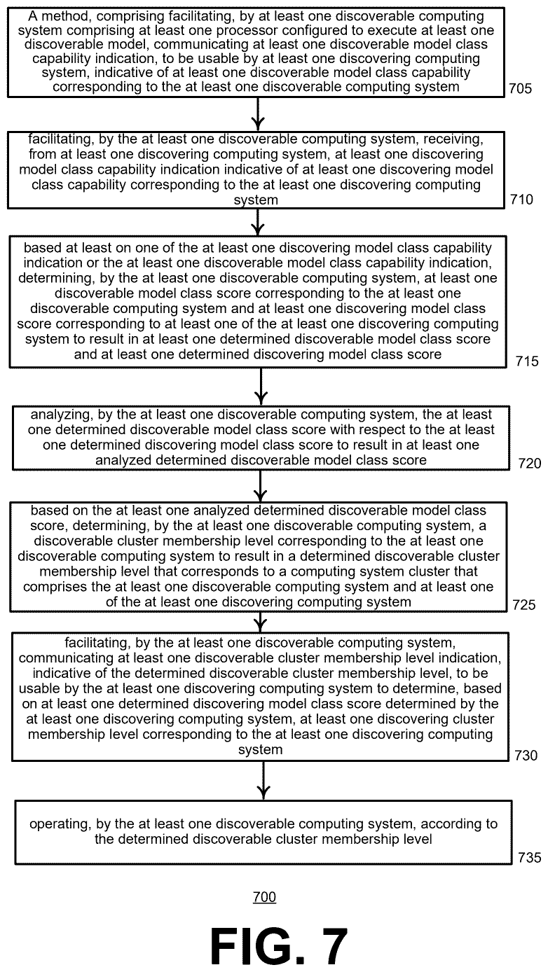

Turning now to FIG. 7, the figure illustrates an example embodiment method 700 comprising at block 705 facilitating, by at least one discoverable computing system comprising at least one processor configured to execute at least one discoverable model, communicating at least one discoverable model class capability indication, to be usable by at least one discovering computing system, indicative of at least one discoverable model class capability corresponding to the at least one discoverable computing system; at block 710 facilitating, by the at least one discoverable computing system, receiving, from at least one discovering computing system, at least one discovering model class capability indication indicative of at least one discovering model class capability corresponding to the at least one discovering computing system; at block 715 based at least on one of the at least one discovering model class capability indication or the at least one discoverable model class capability indication, determining, by the at least one discoverable computing system, at least one discoverable model class score corresponding to the at least one discoverable computing system and at least one discovering model class score corresponding to at least one of the at least one discovering computing system to result in at least one determined discoverable model class score and at least one determined discovering model class score; at block 720 analyzing, by the at least one discoverable computing system, the at least one determined discoverable model class score with respect to the at least one determined discovering model class score to result in at least one analyzed determined discoverable model class score; at block 725 based on the at least one analyzed determined discoverable model class score, determining, by the at least one discoverable computing system, a discoverable cluster membership level corresponding to the at least one discoverable computing system to result in a determined discoverable cluster membership level that corresponds to a computing system cluster that comprises the at least one discoverable computing system and at least one of the at least one discovering computing system; at block 730 facilitating, by the at least one discoverable computing system, communicating at least one discoverable cluster membership level indication, indicative of the determined discoverable cluster membership level, to be usable by the at least one discovering computing system to determine, based on at least one determined discovering model class score determined by the at least one discovering computing system, at least one discovering cluster membership level corresponding to the at least one discovering computing system; and at block 735 operating, by the at least one discoverable computing system, according to the determined discoverable cluster membership level.

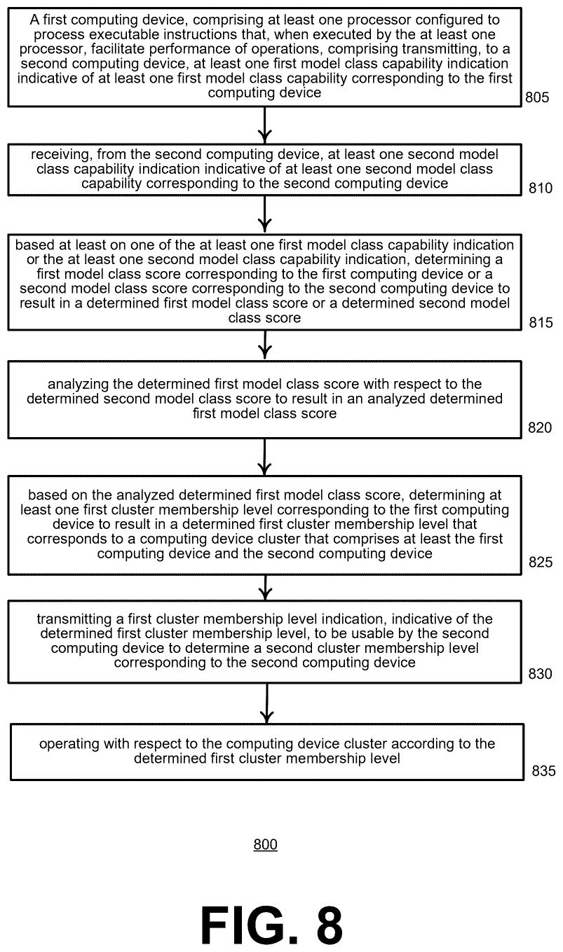

Turning now to FIG. 8, the figure illustrates a first computing device, comprising at block 805 at least one processor configured to process executable instructions that, when executed by the at least one processor, facilitate performance of operations, comprising transmitting, to a second computing device, at least one first model class capability indication indicative of at least one first model class capability corresponding to the first computing device; at block 810 receiving, from the second computing device, at least one second model class capability indication indicative of at least one second model class capability corresponding to the second computing device; at block 815 based at least on one of the at least one first model class capability indication or the at least one second model class capability indication, determining a first model class score corresponding to the first computing device or a second model class score corresponding to the second computing device to result in a determined first model class score or a determined second model class score; at block 820 analyzing the determined first model class score with respect to the determined second model class score to result in an analyzed determined first model class score; at block 825 based on the analyzed determined first model class score, determining at least one first cluster membership level corresponding to the first computing device to result in a determined first cluster membership level that corresponds to a computing device cluster that comprises at least the first computing device and the second computing device; at block 830 transmitting a first cluster membership level indication, indicative of the determined first cluster membership level, to be usable by the second computing device to determine a second cluster membership level corresponding to the second computing device; and at block 835 operating with respect to the computing device cluster according to the determined first cluster membership level.

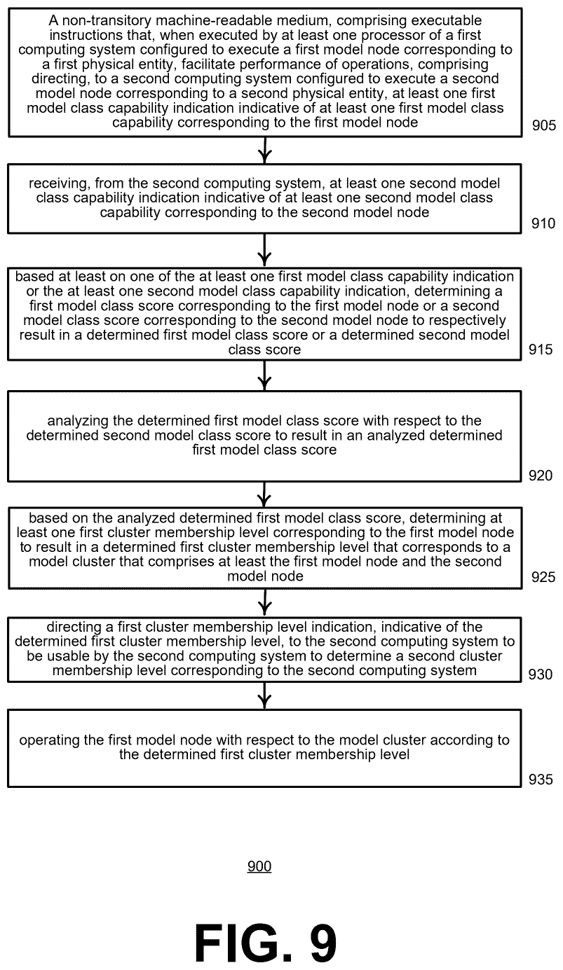

Turning now to FIG. 9, the figure illustrates a non-transitory machine-readable medium 900 comprising at block 905 executable instructions that, when executed by at least one processor of a first computing system configured to execute a first model node corresponding to a first physical entity, facilitate performance of operations, comprising directing, to a second computing system configured to execute a second model node corresponding to a second physical entity, at least one first model class capability indication indicative of at least one first model class capability corresponding to the first model node; at block 910 receiving, from the second computing system, at least one second model class capability indication indicative of at least one second model class capability corresponding to the second model node; at block 915 based at least on one of the at least one first model class capability indication or the at least one second model class capability indication, determining a first model class score corresponding to the first model node or a second model class score corresponding to the second model node to respectively result in a determined first model class score or a determined second model class score; at block 920 analyzing the determined first model class score with respect to the determined second model class score to result in an analyzed determined first model class score; at block 925 based on the analyzed determined first model class score, determining at least one first cluster membership level corresponding to the first model node to result in a determined first cluster membership level that corresponds to a model cluster that comprises at least the first model node and the second model node; at block 930 directing a first cluster membership level indication, indicative of the determined first cluster membership level, to the second computing system to be usable by the second computing system to determine a second cluster membership level corresponding to the second computing system; and at block 935 operating the first model node with respect to the model cluster according to the determined first cluster membership level.

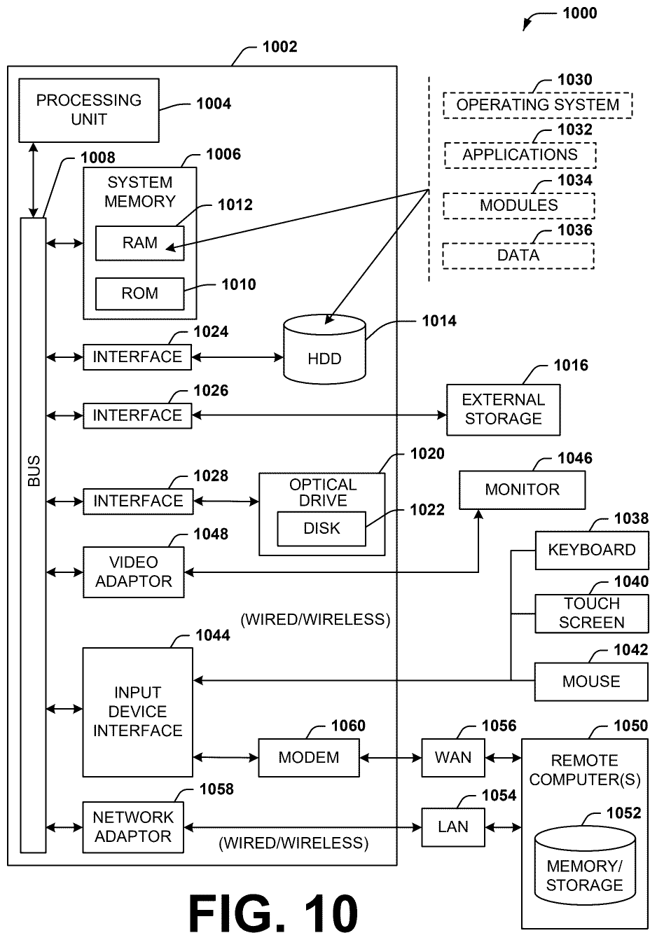

In order to provide additional context for various embodiments described herein, FIG. 10 and the following discussion are intended to provide a brief, general description of a suitable computing environment 1000 in which various embodiments of the embodiment described herein can be implemented. While embodiments have been described above in the general context of computer-executable instructions that can run on one or more computers, those skilled in the art will recognize that the embodiments can be also implemented in combination with other program modules and/or as a combination of hardware and software.

Generally, program modules include routines, programs, components, data structures, etc., that perform particular tasks or implement particular abstract data types. Moreover, those skilled in the art will appreciate that the methods can be practiced with other computer system configurations, including single-processor or multiprocessor computer systems, minicomputers, mainframe computers, IoT devices, distributed computing systems, as well as personal computers, hand-held computing devices, microprocessor-based or programmable consumer electronics, and the like, each of which can be operatively coupled to one or more associated devices.

The embodiments illustrated herein can be also practiced in distributed computing environments where certain tasks are performed by remote processing devices that are linked through a communications network. In a distributed computing environment, program modules can be located in both local and remote memory storage devices.

Computing devices typically include a variety of media, which can include computer-readable storage media, machine-readable storage media, and/or communications media, which two terms are used herein differently from one another as follows. Computer-readable storage media or machine-readable storage media can be any available storage media that can be accessed by the computer and includes both volatile and nonvolatile media, removable and non-removable media. By way of example, and not limitation, computer-readable storage media or machine-readable storage media can be implemented in connection with any method or technology for storage of information such as computer-readable or machine-readable instructions, program modules, structured data or unstructured data.

Computer-readable storage media can include, but are not limited to, random access memory (RAM), read only memory (ROM), electrically erasable programmable read only memory (EEPROM), flash memory or other memory technology, compact disk read only memory (CD-ROM), digital versatile disk (DVD), Blu-ray disc (BD) or other optical disk storage, magnetic cassettes, magnetic tape, magnetic disk storage or other magnetic storage devices, solid state drives or other solid state storage devices, or other tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

With reference again to FIG. 10, the example environment 1000 for implementing various embodiments described herein includes a computer 1002, the computer 1002 including a processing unit 1004, a system memory 1006 and a system bus 1008. The system bus 1008 couples system components including, but not limited to, the system memory 1006 to the processing unit 1004. The processing unit 1004 can be any of various commercially available processors and may include a cache memory. Dual microprocessors and other multi-processor architectures can also be employed as the processing unit 1004.

The system bus 1008 can be any of several types of bus structure that can further interconnect to a memory bus (with or without a memory controller), a peripheral bus, and a local bus using any of a variety of commercially available bus architectures. The system memory 1006 includes ROM 1010 and RAM 1012. A basic input/output system (BIOS) can be stored in a non-volatile memory such as ROM, erasable programmable read only memory (EPROM), EEPROM, which BIOS contains the basic routines that help to transfer information between elements within the computer 1002, such as during startup. The RAM 1012 can also include a high-speed RAM such as static RAM for caching data.

Computer 1002 further includes an internal hard disk drive (HDD) 1014 (e.g., EIDE, SATA), one or more external storage devices 1016 (e.g., a magnetic floppy disk drive (FDD) 1016, a memory stick or flash drive reader, a memory card reader, etc.) and an optical disk drive 1020 (e.g., which can read or write from a CD-ROM disc, a DVD, a BD, etc.). While the internal HDD 1014 is illustrated as located within the computer 1002, the internal HDD 1014 can also be configured for external use in a suitable chassis (not shown). Additionally, while not shown in environment 1000, a solid-state drive (SSD) could be used in addition to, or in place of, an HDD 1010. The HDD 1014, external storage device(s) 1016 and optical disk drive 1020 can be connected to the system bus 1008 by an HDD interface 1024, an external storage interface 1026 and an optical drive interface 1028, respectively. The interface 1024 for external drive implementations can include at least one or both of Universal Serial Bus (USB) and Institute of Electrical and Electronics Engineers (IEEE) 1394 interface technologies. Other external drive connection technologies are within contemplation of the embodiments described herein.

The drives and their associated computer-readable storage media provide nonvolatile storage of data, data structures, computer-executable instructions, and so forth. For the computer 1002, the drives and storage media accommodate the storage of any data in a suitable digital format. Although the description of computer-readable storage media above refers to respective types of storage devices, it should be appreciated by those skilled in the art that other types of storage media which are readable by a computer, whether presently existing or developed in the future, could also be used in the example operating environment, and further, that any such storage media can contain computer-executable instructions for performing the methods described herein.

A number of program modules can be stored in the drives and RAM 1012, including an operating system 1030, one or more application programs 1032, other program modules 1034 and program data 1036. All or portions of the operating system, applications, modules, and/or data can also be cached in the RAM 1012. The systems and methods described herein can be implemented utilizing various commercially available operating systems or combinations of operating systems.

Computer 1002 can optionally comprise emulation technologies. For example, a hypervisor (not shown) or other intermediary can emulate a hardware environment for operating system 1030, and the emulated hardware can optionally be different from the hardware illustrated in FIG. 10. In such an embodiment, operating system 1030 can comprise one virtual machine (VM) of multiple VMs hosted at computer 1002. Furthermore, operating system 1030 can provide runtime environments, such as the Java runtime environment or the . NET framework, for applications 1032. Runtime environments are consistent execution environments that allow applications 1032 to run on any operating system that includes the runtime environment. Similarly, operating system 1030 can support containers, and applications 1032 can be in the form of containers, which are lightweight, standalone, executable packages of software that include, e.g., code, runtime, system tools, system libraries and settings for an application.

Further, computer 1002 can comprise a security module, such as a trusted processing module (TPM). For instance, with a TPM, boot components hash next in time boot components, and wait for a match of results to secured values, before loading a next boot component. This process can take place at any layer in the code execution stack of computer 1002, e.g., applied at the application execution level or at the operating system (OS) kernel level, thereby enabling security at any level of code execution.

A user can enter commands and information into the computer 1002 through one or more wired/wireless input devices, e.g., a keyboard 1038, a touch screen 1040, and a pointing device, such as a mouse 1042. Other input devices (not shown) can include a microphone, an infrared (IR) remote control, a radio frequency (RF) remote control, or other remote control, a joystick, a virtual reality controller and/or virtual reality headset, a game pad, a stylus pen, an image input device, e.g., camera(s), a gesture sensor input device, a vision movement sensor input device, an emotion or facial detection device, a biometric input device, e.g., fingerprint or iris scanner, or the like. These and other input devices are often connected to the processing unit 1004 through an input device interface 1044 that can be coupled to the system bus 1008, but can be connected by other interfaces, such as a parallel port, an IEEE 1394 serial port, a game port, a USB port, an IR interface, a BLUETOOTH® interface, etc.

A monitor 1046 or other type of display device can be also connected to the system bus 1008 via an interface, such as a video adapter 1048. In addition to the monitor 1046, a computer typically includes other peripheral output devices (not shown), such as speakers, printers, etc.

The computer 1002 can operate in a networked environment using logical connections via wired and/or wireless communications to one or more remote computers, such as a remote computer(s) 1050. The remote computer(s) 1050 can be a workstation, a server computer, a router, a personal computer, portable computer, microprocessor-based entertainment appliance, a peer device or other common network node, and typically includes many or all of the elements described relative to the computer 1002, although, for purposes of brevity, only a memory/storage device 1052 is illustrated. The logical connections depicted include wired/wireless connectivity to a local area network (LAN) 1054 and/or larger networks, e.g., a wide area network (WAN) 1056. Such LAN and WAN networking environments are commonplace in offices and companies, and facilitate enterprise-wide computer networks, such as intranets, all of which can connect to a global communications network, e.g., the internet.

When used in a LAN networking environment, the computer 1002 can be connected to the local network 1054 through a wired and/or wireless communication network interface or adapter 1058. The adapter 1058 can facilitate wired or wireless communication to the LAN 1054, which can also include a wireless access point (AP) disposed thereon for communicating with the adapter 1058 in a wireless mode.

When used in a WAN networking environment, the computer 1002 can include a modem 1060 or can be connected to a communications server on the WAN 1056 via other means for establishing communications over the WAN 1056, such as by way of the internet. The modem 1060, which can be internal or external and a wired or wireless device, can be connected to the system bus 1008 via the input device interface 1044. In a networked environment, program modules depicted relative to the computer 1002 or portions thereof, can be stored in the remote memory/storage device 1052. It will be appreciated that the network connections shown are examples and other means of establishing a communications link between the computers can be used.

When used in either a LAN or WAN networking environment, the computer 1002 can access cloud storage systems or other network-based storage systems in addition to, or in place of, external storage devices 1016 as described above. Generally, a connection between the computer 1002 and a cloud storage system can be established over a LAN 1054 or WAN 1056 e.g., by the adapter 1058 or modem 1060, respectively. Upon connecting the computer 1002 to an associated cloud storage system, the external storage interface 1026 can, with the aid of the adapter 1058 and/or modem 1060, manage storage provided by the cloud storage system as it would other types of external storage. For instance, the external storage interface 1026 can be configured to provide access to cloud storage sources as if those sources were physically connected to the computer 1002.

The computer 1002 can be operable to communicate with any wireless devices or entities operatively disposed in wireless communication, e.g., a printer, scanner, desktop and/or portable computer, portable data assistant, communications satellite, any piece of equipment or location associated with a wirelessly detectable tag (e.g., a kiosk, news stand, store shelf, etc.), and telephone. This can include Wireless Fidelity (Wi-Fi) and BLUETOOTH® wireless technologies. Thus, the communication can be a predefined structure as with a conventional network or simply an ad hoc communication between at least two devices.

The above description includes non-limiting examples of the various embodiments. It is, of course, not possible to describe every conceivable combination of components or methodologies for purposes of describing the disclosed subject matter, and one skilled in the art may recognize that further combinations and permutations of the various embodiments are possible. The disclosed subject matter is intended to embrace all such alterations, modifications, and variations that fall within the spirit and scope of the appended claims.

With regard to the various functions performed by the above-described components, devices, circuits, systems, etc., the terms (including a reference to a “means”) used to describe such components are intended to also include, unless otherwise indicated, any structure(s) which performs the specified function of the described component (e.g., a functional equivalent), even if not structurally equivalent to the disclosed structure. In addition, while a particular feature of the disclosed subject matter may have been disclosed with respect to only one of several implementations, such feature may be combined with one or more other features of the other implementations as may be desired and advantageous for any given or particular application.

The terms “exemplary” and/or “demonstrative” or variations thereof as may be used herein are intended to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent structures and techniques known to one skilled in the art. Furthermore, to the extent that the terms “includes,” “has,” “contains,” and other similar words are used in either the detailed description or the claims, such terms are intended to be inclusive in a manner similar to the term “comprising” as an open transition word-without precluding any additional or other elements.

The term “or” as used herein is intended to mean an inclusive “or” rather than an exclusive “or.” For example, the phrase “A or B” is intended to include instances of A, B, and both A and B. Additionally, the articles “a” and “an” as used in this application and the appended claims should generally be construed to mean “one or more” unless either otherwise specified or clear from the context to be directed to a singular form.

The term “set” as employed herein excludes the empty set, i.e., the set with no elements therein. Thus, a “set” in the subject disclosure includes one or more elements or entities. Likewise, the term “group” as utilized herein refers to a collection of one or more entities.

The terms “first,” “second,” “third,” and so forth, as used in the claims, unless otherwise clear by context, is for clarity only and doesn't otherwise indicate or imply any order in time. For instance, “a first determination,” “a second determination,” and “a third determination,” does not indicate or imply that the first determination is to be made before the second determination, or vice versa, etc.

The description of illustrated embodiments of the subject disclosure as provided herein, including what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as one skilled in the art can recognize. In this regard, while the subject matter has been described herein in connection with various embodiments and corresponding drawings, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

What is claimed is:

1. A method, comprising:
facilitating, by at least one discoverable computing system comprising at least one processor configured to execute at least one discoverable model, communicating at least one discoverable model class capability indication, to be usable by at least one discovering computing system, indicative of at least one discoverable model class capability corresponding to the at least one discoverable computing system;
facilitating, by the at least one discoverable computing system, receiving, from at least one discovering computing system, at least one discovering model class capability indication indicative of at least one discovering model class capability corresponding to the at least one discovering computing system;
based at least on one of the at least one discovering model class capability indication or the at least one discoverable model class capability indication, determining, by the at least one discoverable computing system, at least one discoverable model class score corresponding to the at least one discoverable computing system and at least one discovering model class score corresponding to at least one of the at least one discovering computing system to result in at least one determined discoverable model class score and at least one determined discovering model class score;
analyzing, by the at least one discoverable computing system, the at least one determined discoverable model class score with respect to the at least one determined discovering model class score to result in at least one analyzed determined discoverable model class score;
based on the at least one analyzed determined discoverable model class score, determining, by the at least one discoverable computing system, a discoverable cluster membership level corresponding to the at least one discoverable computing system to result in a determined discoverable cluster membership level that corresponds to a computing system cluster that comprises the at least one discoverable computing system and at least one of the at least one discovering computing system;
facilitating, by the at least one discoverable computing system, communicating at least one discoverable cluster membership level indication, indicative of the determined discoverable cluster membership level, to be usable by the at least one discovering computing system to determine, based on at least one determined discovering model class score determined by the at least one discovering computing system, at least one discovering cluster membership level corresponding to the at least one discovering computing system; and
operating, by the at least one discoverable computing system, according to the determined discoverable cluster membership level.

2. The method of claim 1, wherein the determined discoverable cluster membership level comprises a leader level corresponding to the at least one discoverable computing system being a leader of the computing system cluster.

3. The method of claim 2, wherein the at least one determined discoverable model class score is determined to be higher than the at least one determined discovering model class score.

4. The method of claim 3, wherein the at least one determined discoverable model class score is determined to be higher than the at least one determined discovering model class score by the at least one discoverable computing system.

5. The method of claim 3, wherein the at least one determined discoverable model class score is determined to be higher than the at least one determined discovering model class score by the at least one discovering computing system.

6. The method of claim 2, wherein the at least one determined discoverable cluster membership level is a first determined discoverable cluster membership level, wherein the at least one determined discoverable model class score is a first determined discoverable model class score, wherein the at least one discoverable cluster membership level indication is a first discoverable cluster membership level indication, and wherein the method further comprises:
determining, by the at least one discoverable computing system a second determined discoverable model class score;
determining, by the at least one discoverable computing system, a second determined discovering model class score corresponding to the at least one discovering computing system;
based on the second determined discovering model class score being determined to not be greater than the second determined discoverable model class score, determining, by the at least one discoverable computing system, a second discoverable cluster membership level that does not comprise a leader level corresponding to the at least one discoverable computing system being a leader of the computing system cluster; and
facilitating, by the at least one discoverable computing system, communicating, to the at least one discovering computing system, a second discoverable cluster membership level indication indicative of the second discoverable cluster membership level indication.

7. The method of claim 2, further comprising:
facilitating, by the at least one discoverable computing system, communicating, to the at least one discovering computing system cluster, configuration information comprising at least one of: at least one cluster indication indicative of the computing system cluster, a ping periodicity indication indicative of at least one ping periodicity according to which the at least one discoverable computing system is to communicate acknowledgements with respect to the at least one discovering computing system, at least one cluster score criterion to be applicable with respect to the to the at least one discoverable model class score or the at least one discovering model class score to be used to determine membership in the computing system cluster, at least one score offset to be applicable with respect to analysis of the at least one discoverable model class score or the at least one discovering model class score with respect to the at least one cluster score criterion, or at least one score calculation mode indication indicative of at least one score calculation mode.

8. The method of claim 7, wherein the at least one score calculation mode indication comprises at least one of: a local mode indication indicative that the at least one discovering model class score is to be determined by the at least one discovering computing system or an external mode indicative of the at least one discovering model class to be determined by the at least on discoverable computing system.

9. The method of claim 1, wherein the determining of the at least one determined discoverable model class score is determined based on at least one of: the at least one discoverable model class capability or the at least one discovering model class capability, at least one confidence level corresponding to at least one of the at least one discoverable computing system or the at least one discovering computing system, at least one prediction accuracy corresponding to at least one of the at least one discoverable computing system or the at least one discovering computing system, at least one network connectivity quality corresponding to at least one of the at least one discoverable computing system or the at least one discovering computing system, at least one energy efficiency corresponding to at least one of the at least one discoverable computing system or the at least one discovering computing system, at least one data freshness value corresponding to at least one of the at least one discoverable computing system or the at least one discovering computing system, or at least one update periodicity corresponding to at least one of the at least one discoverable computing system or the at least one discovering computing system.

10. The method of claim 9, wherein the at least one determined discoverable model class score is prioritized based on the at least one confidence level.

11. The method of claim 1, wherein the at least one determined discovering model class score is to be determined by the at least one discovering computing system based on at least one of: the at least one discoverable model class capability or the at least one discovering model class capability, at least one confidence level corresponding to at least one of the at least one discoverable computing system or the at least one discovering computing system, at least one prediction accuracy corresponding to at least one of the at least one discoverable computing system or the at least one discovering computing system, at least one network connectivity quality corresponding to at least one of the at least one discoverable computing system or the at least one discovering computing system, at least one energy efficiency corresponding to at least one of the at least one discoverable computing system or the at least one discovering computing system, at least one data freshness value corresponding to at least one of the at least one discoverable computing system or the at least one discovering computing system, or at least one update periodicity corresponding to at least one of the at least one discoverable computing system or the at least one discovering computing system.

12. The method of claim 11, wherein at least one of the at least one discoverable model or the at least on discovering model comprises at least one digital twin model.

13. A first computing device, comprising at least one processor configured to process executable instructions that, when executed by the at least one processor, facilitate performance of operations, comprising:
transmitting, to a second computing device, at least one first model class capability indication indicative of at least one first model class capability corresponding to the first computing device;
receiving, from the second computing device, at least one second model class capability indication indicative of at least one second model class capability corresponding to the second computing device;
based at least on one of the at least one first model class capability indication or the at least one second model class capability indication, determining a first model class score corresponding to the first computing device or a second model class score corresponding to the second computing device to result in a determined first model class score or a determined second model class score;
analyzing the determined first model class score with respect to the determined second model class score to result in an analyzed determined first model class score;
based on the analyzed determined first model class score, determining at least one first cluster membership level corresponding to the first computing device to result in a determined first cluster membership level that corresponds to a computing device cluster that comprises at least the first computing device and the second computing device;
transmitting a first cluster membership level indication, indicative of the determined first cluster membership level, to be usable by the second computing device to determine a second cluster membership level corresponding to the second computing device; and
operating with respect to the computing device cluster according to the determined first cluster membership level.

14. The first computing device of claim 13, wherein the at least one first cluster membership level corresponds to the first computing device being a cluster master corresponding to the computing device cluster, wherein the operating according to the determined first cluster membership level comprises managing model output report information corresponding to the computing device cluster, and wherein the operations further comprise:
transmitting, to the second computing device, at least one acknowledgement request;
failing to receive, from the second computing device, at least one acknowledgement response responsive to the at least one acknowledgement request to result in at least one failed acknowledgement;
based on the at least one failed acknowledgement, transmitting, to the second computing device, at least one master halting indication indicative that the first computing device is not the cluster master; and
halting the managing model output report information corresponding to the computing device cluster.

15. The first computing device of claim 13, wherein the at least one first cluster membership level corresponds to the first computing device being a cluster non-master corresponding to the computing device cluster, and wherein the operations further comprise:
determining an updated first model class score corresponding to the first computing device to result in a determined updated first model class score;
based on the determined updated first model class score, determining an updated first cluster membership level corresponding to the first computing device to result in a determined updated first cluster membership level that corresponds to the computing device cluster;
transmitting an updated first cluster membership level indication, indicative of the determined updated first cluster membership level corresponding to the first computing device being a master of the computing device cluster; and
operating with respect to the computing device cluster according to the determined updated first cluster membership level, wherein the operating according to the determined updated first cluster membership level comprises managing model output report information corresponding to the computing device cluster.

16. The first computing device of claim 13, wherein the first computing device comprises a first wireless transmit receive unit, wherein the second computing device comprises at least one second wireless transmit receive unit, wherein the computing device cluster comprises a sidelink group comprising the first computing device and the second computing device, wherein the sidelink group comprises the first computing device being a remote wireless transmit receive unit and the second computing device being a relay wireless transmit receive unit, and wherein the first computing device is a leader of the computing device cluster configured to facilitate communication between the second computing device and a wireless radio access network node according to at least one sidelink channel resource corresponding to the sidelink group.

17. A non-transitory machine-readable medium, comprising executable instructions that, when executed by at least one processor of a first computing system configured to execute a first model node corresponding to a first physical entity, facilitate performance of operations, comprising:
directing, to a second computing system configured to execute a second model node corresponding to a second physical entity, at least one first model class capability indication indicative of at least one first model class capability corresponding to the first model node;
receiving, from the second computing system, at least one second model class capability indication indicative of at least one second model class capability corresponding to the second model node;
based at least on one of the at least one first model class capability indication or the at least one second model class capability indication, determining a first model class score corresponding to the first model node or a second model class score corresponding to the second model node to respectively result in a determined first model class score or a determined second model class score;
analyzing the determined first model class score with respect to the determined second model class score to result in an analyzed determined first model class score;
based on the analyzed determined first model class score, determining at least one first cluster membership level corresponding to the first model node to result in a determined first cluster membership level that corresponds to a model cluster that comprises at least the first model node and the second model node;
directing a first cluster membership level indication, indicative of the determined first cluster membership level, to the second computing system to be usable by the second computing system to determine a second cluster membership level corresponding to the second computing system; and
operating the first model node with respect to the model cluster according to the determined first cluster membership level.

18. The non-transitory machine-readable medium of claim 17, wherein at least one of the first model class score or the second model class score are based on at least one of: at least one inter-node latency between the first model node and the second model node, at least one bandwidth availability corresponding to at least one of the first model node or the second model node, or at least one computational load distribution corresponding to a first computational loading corresponding to the first model node or a second computational loading corresponding to the second model node.

19. The non-transitory machine-readable medium of claim 17, wherein at least one of the first model node or the second model node corresponds to a first digital twin node or a second digital twin node, respectively, and wherein the first digital twin node or second digital twin node are configured to determine at least one parameter metric corresponding to at least one parameter associated with the model cluster.

20. The non-transitory machine-readable medium of claim 19, wherein at least one of the first digital twin node or the second digital twin node corresponds to a vehicle entity cluster, and wherein at least one vehicle entity associated with the vehicle entity cluster is configured to use information generated by the first digital twin node or the second digital twin node to facilitate operation of the at least one vehicle entity.
